(19) United States
(12) Patent Application Publication
(10) Pub. No.: US 2014/0182812 A1
(43) Pub. Date: Jul. 3, 2014

(54) COOLING SYSTEM

(71) Applicant: HON HAI PRECISION INDUSTRY CO., LTD., New Taipei (TW)

(72) Inventor: TAI-WEI LIN, New Taipei (TW)

(73) Assignee: HON HAI PRECISION INDUSTRY CO., LTD., New Taipei (TW)

(21) Appl. No.: 13/749,701

(22) Filed: Jan. 25, 2013

(30) Foreign Application Priority Data
Dec. 28, 2012 (TW) 101150743

(51) Int. Cl. H05K 7/20

(52) U.S. Cl. CPC H05K 7/20145
USPC 165/57; 454/252

(57) ABSTRACT

A cooling system includes a room, a container data center, and an air duct. The room includes a floor, and defines a receiving space above the floor, and a heat-dissipation space below the floor. The container data center is supported on the floor. The container data center includes a container. The container includes an end wall defining a number of air inlets and a sidewall defining a number of air outlets. The air duct defines a number of vents and an opening communicating with the vents. The air duct is installed to an outer surface of the sidewall, and the vents are aligning with air outlets of the sidewall. The floor defines a number of through holes communicating with the opening of the air duct and the heat-dissipation space.

### BACKGROUND

1. Technical Field

The present disclosure relates to a system for cooling container data centers.

2. Description of Related Art

In a warehouse computing facility, a number of container data centers can be stored in the room for data centralization. Each container data center includes a container and a plurality of cabinets received in the container. Each cabinet includes a number of servers generating a great amount of heat during operation. The heat needs to be dissipated timely to ensure the proper functioning of the container data centers. Presently, the room includes a sidewall defining a plurality of openings. Each container defines an air inlet and an air outlet. Air enters the room through the openings, and flows into the containers through the air inlets, to cool the servers of the cabinets. However, the heat is dissipated out to the interior of the room creating a heated environment for all of the containers.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an exemplary embodiment of a cooling system, wherein the cooling system includes a plurality of container data centers in a room.

FIG. 2 is an exploded, isometric view of one of the container data centers of FIG. 1.

FIG. 3 is a partial, cross-sectional view of FIG. 2, taken along the line of III-III.

FIG. 4 is a partial, cross-sectional view of FIG. 1, taken along the line of IV-IV.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

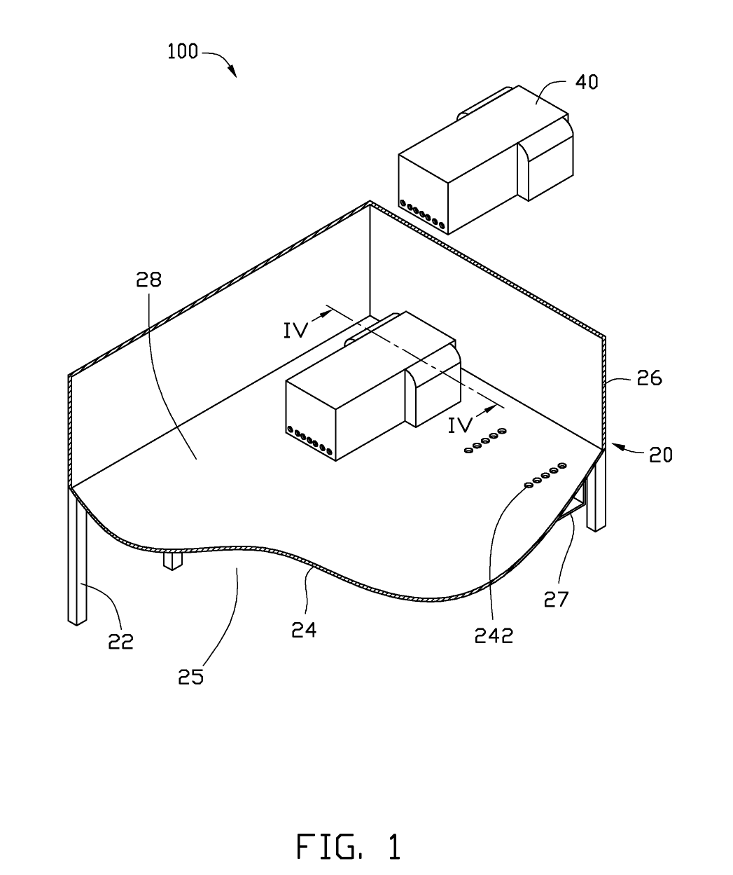

FIG. 1 shows an embodiment of a cooling system 100 including a room 20 and a plurality of container data centers 40.

The room 20 includes a plurality of supporting poles 22, a floor 24 supported on the supporting poles 22, and a sidewall 26 extending up from edges of the floor 24. The floor 24 and the sidewall 26 cooperatively bound a receiving space 28. The floor 24 and the supporting poles 22 cooperatively bound a heat-dissipation space 25. A ventilation pipe 27 is received in the heat-dissipation space 25 and is mounted on a bottom of the floor 24. The floor 24 defines a plurality of rows of through holes 242 communicating with the ventilation pipe 27.

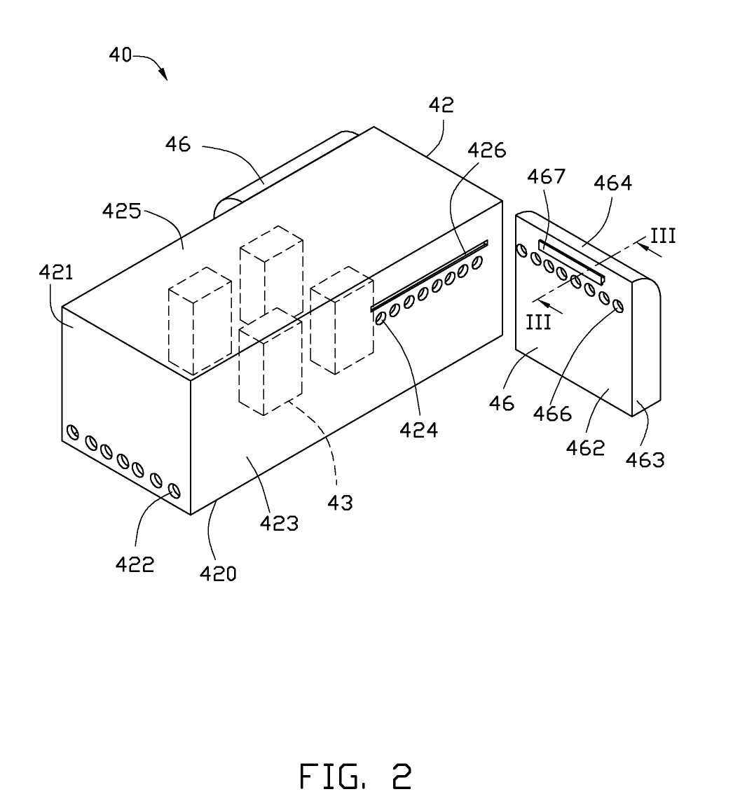

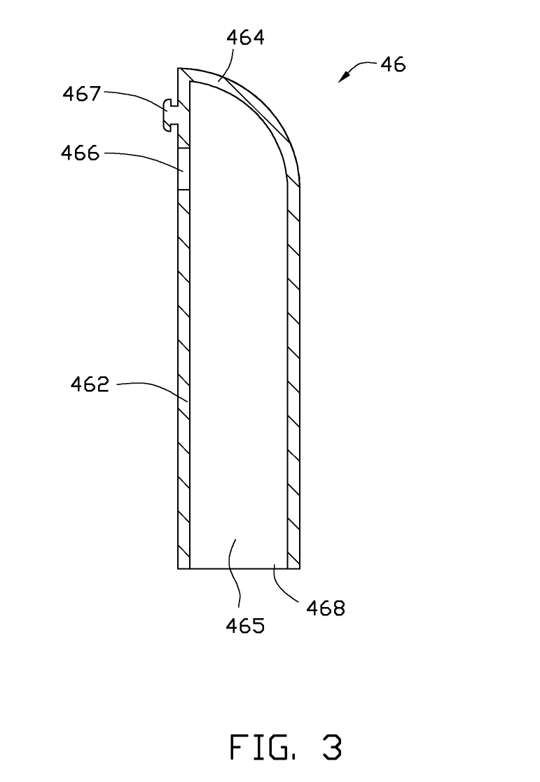

FIG. 2 and FIG. 3 show each container data center 40 including a container 42, a plurality of cabinets 43 received in the container 42, and two air ducts 46. The container 42 includes a rectangular bottom wall 420, two end walls 421 perpendicularly extending up from two opposite ends of the bottom wall 420, two sidewalls 423 perpendicularly extending up from two opposite sides of the bottom wall 420, and a top wall 425 connected to tops of the sidewalls 423 and the end walls 421. One of the end walls 421 defines a plurality of air inlets 422 adjacent to the bottom wall 420. Two sidewalls 423 each define a plurality of air outlets 424 away from the air inlets 422. The air outlets 424 are arrayed in a line parallel and adjacent to the top wall 425. Each sidewall 423 defines a long sliding slot 426 above the corresponding air outlets 424 and parallel to the top wall 425. Each cabinet 43 receives a plurality of servers (not shown).

Each air duct 46 is substantially rectangular, and includes two opposite side plates 462, two opposite end plates 463 connected between corresponding ends of the side plates 462, and a top plate 464 connected to tops of the side plates 462 and the end plates 463. The side plates 462, the end plates 463, and the top plate 464 cooperatively bound an airflow channel 465. An opening 468 is defined in the air duct 46, communicating with the airflow channel 465 and away from the top plate 464. One of the side plates 462 defines a plurality of vents 466 communicating with the airflow channel 465 and adjacent to the top plate 464. The vents 466 are arrayed in a line parallel to the top plate 464. A resilient guiding bar 467 protrudes out from the side plate 462, between the top plate 464 and the vents 466. In the embodiment, the air duct 46 is made of resilient material, such as plastic.

In assembly, the guiding bar 467 of each air duct 46 is slidably inserted into the corresponding slot 426 of the container 42, to allow the vents 466 of the air duct 46 to align with the corresponding air outlets 424 of the container 42. The container data centers 40 are supported on the floor 24, and the openings 468 of the air ducts 46 are aligned with the corresponding rows of through holes 242.

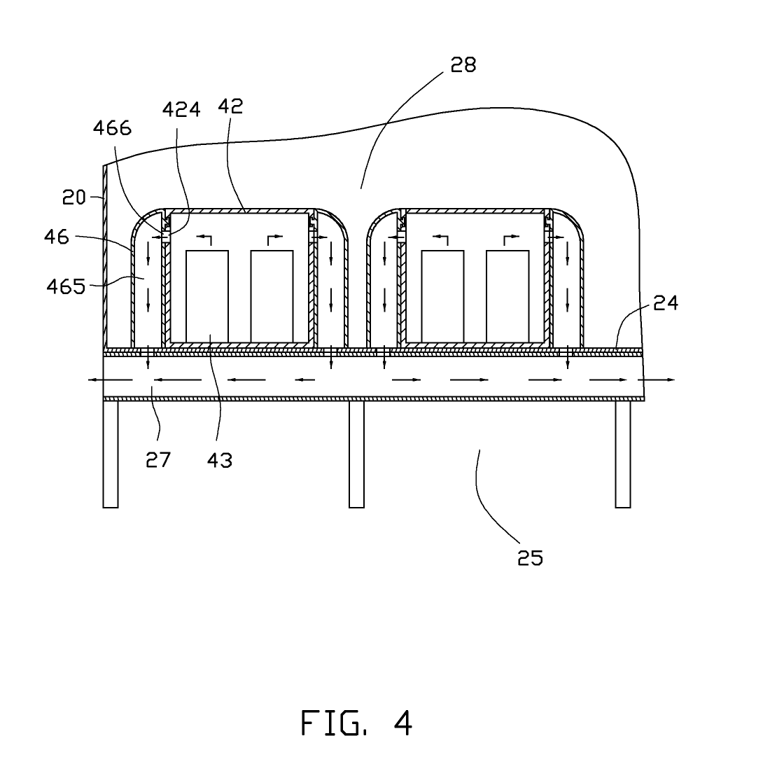

Referring to FIG. 4, in use, air enters each container 40 through the corresponding air inlets 422, and flows through the cabinets 43. A great amount of heat generated by the cabinets 43 is dissipated out of the container 40 through the air outlets 424. The heated air enters the airflow channels 465 of the air ducts 46 through the vents 466, and flows into the ventilation pipe 27 through the openings 468 and the through holes 242. The heat can be dissipated out of the containers 42 through the ventilation pipe 27, and will not enter the receiving space 28 of the room 20.

While the disclosure describes examples and embodiments, it is to be understood that the disclosure is not limited thereto. On the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A cooling system, comprising:
a room comprising a floor, and defining a receiving space above the floor, and a heat-dissipation space below the floor;
a container data center comprising a container, wherein the container comprises an end wall defining a plurality of air inlets and a sidewall defining a plurality of air outlets; and
an air duct defining a plurality of vents, and an opening communicating with the plurality of vents;
wherein the air duct is installed to an outer surface of the sidewall, and the plurality of vents is aligned with the plurality of air outlets of the sidewall, the container is supported on the floor, the floor defines a plurality of through holes communicating with the opening of the air duct and the heat-dissipation space.

2. The cooling system of claim 1, wherein an ventilation pipe is received in the heat-dissipation space, the plurality of through holes of the floor communicates with the ventilation pipe.

3. The cooling system of claim 1, wherein the plurality of air inlets is defined in a lower portion of the end wall.

4. The cooling system of claim 1, wherein the plurality of air outlets is defined in an upper portion of the sidewall, away from the plurality of air inlets, and the plurality of air outlets is arrayed in a line parallel to the floor of the room.

5. The cooling system of claim 4, wherein the air duct is rectangular, and comprises two opposite side plates, two opposite end plates connected between corresponding ends of the side plates, and a top plate connected to tops of the side plates and the end plates, the side plates, the end plates, and the top plate cooperatively bound an airflow channel, the plurality of vents is defined in one of the side plates and communicates with the airflow channel, the opening communicates with the airflow channel away from the plurality of vents.

6. The cooling system of claim 5, wherein the sidewall defines a sliding slot above the plurality of air outlets, a resilient sliding bar protrudes out from the side plate of the air duct above the plurality of vents, the sliding bar is slidably inserted into the sliding slot of the container.

7. The cooling system of claim 6, wherein the air duct is made of resilient material.
